(19) United States
(12) Patent Application Publication
(10) Pub. No.: US 2006/0103442 A1
(43) Pub. Date: May 18, 2006

(54) Memory element with improved soft-error rate

(76) Inventor: Daniel W. Krueger, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/993,014

(22) Filed: Nov. 18, 2004

(51) Int. Cl. H03K 3/356

(52) U.S. Cl. 327/208

(57) ABSTRACT

In a preferred embodiment, the invention provides a circuit and method for reducing soft error events in memory elements. A first transfer gate is connected to an first input of a first tristatable inverter, a second input of a second tristatable inverter, and the output of a third tristatable inverter. A second transfer gate is connected to an first input of the second tristatable inverter, a second input of the first tristatable inverter, and the output of a fourth tristatable inverter. The output of the first tristatable inverter is connected to the first input of the third tristatable inverter and the second input of the fourth tristatable inverter. The output of the second tristatable inverter is connected to the second input of the third tristatable inverter and the first input of the fourth tristatable inverter. The input of an inverter is connected to the output of the fourth tristatable inverter.

### FIELD OF THE INVENTION

This invention relates generally to memory element design. More particularly, this invention relates to improving soft error immunity in latches.

### BACKGROUND OF THE INVENTION

High-energy neutrons lose energy in materials mainly through collisions with silicon nuclei that lead to a chain of secondary reactions. These reactions deposit a dense track of electron-hole pairs as they pass through a p-n junction. Some of the deposited charge will recombine, and some will be collected at the junction contacts. When a particle strikes a sensitive region of a latch, the charge that accumulates could exceed the minimum charge that is needed to “flip” the value stored on the latch, resulting in a soft error.

The smallest charge that results in a soft error is called the critical charge of the latch. The rate at which soft errors occur (SER) is typically expressed in terms of failures in time (FIT).

A common source of soft errors are alpha particles which may be emitted by trace amounts of radioactive isotopes present in packing materials of integrated circuits. “Bump” material used in flip-chip packaging techniques has also been identified as a possible source of alpha particles.

Other sources of soft errors include high-energy cosmic rays and solar particles. High-energy cosmic rays and solar particles react with the upper atmosphere generating high-energy protons and neutrons that shower to the earth. Neutrons can be particularly troublesome as they can penetrate most man-made construction (a neutron can easily pass through five feet of concrete). This effect varies with both latitude and altitude. In London, the effect is two times worse than on the equator. In Denver, Colo. with its mile-high altitude, the effect is three times worse than at sea-level San Francisco. In a commercial airplane, the effect can be 100-800 times worse than at sea-level.

Radiation induced soft errors are becoming one of the main contributors to failure rates in microprocessors and other complex ICs (integrated circuits). Several approaches have been suggested to reduce this type of failure. Adding ECC (Error Correction Code) or parity in data paths approaches this problem from an architectural level. Adding ECC or parity in data paths can be complex and costly.

At the circuit level, SER may be reduced by increasing the ratio of capacitance created by oxides to the capacitance created by p/n junctions. The capacitance in a latch, among other types, includes capacitance created by p/n junctions and capacitance created by oxides. Since electron/hole pairs are created as high-energy neutrons pass through a p/n junction, a reduction in the area of p/n junctions in a latch typically decreases the SER. Significant numbers of electron/hole pairs are not created when high-energy neutrons pass through oxides. As a result, the SER may typically be reduced by increasing the ratio of oxide capacitance to p/n junction capacitance in a SRAM cell.

There is a need in the art to reduce the SER in latches. An embodiment of this invention reduces the SER in memory elements.

### SUMMARY OF THE INVENTION

In a preferred embodiment, the invention provides a circuit and method for reducing soft error events in memory elements. A first transfer gate is connected to an first input of a first tristatable inverter, a second input of a second tristatable inverter, and the output of a third tristatable inverter. A second transfer gate is connected to an first input of the second tristatable inverter, a second input of the first tristatable inverter, and the output of a fourth tristatable inverter. The output of the first tristatable inverter is connected to the first input of the third tristatable inverter and the second input of the fourth tristatable inverter. The output of the second tristatable inverter is connected to the second input of the third tristatable inverter and the first input of the fourth tristatable inverter. The input of an inverter is connected to the output of the fourth tristatable inverter.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a schematic diagram of a transfer gate, a latch, and an inverter. Prior Art

FIG. 2 is a schematic diagram of a transfer gate, a latch, and an inverter. Prior Art

FIG. 3 is a schematic diagram of a memory element.

### DETAILED DESCRIPTION OF THE PREFERRED EMBODIMENT

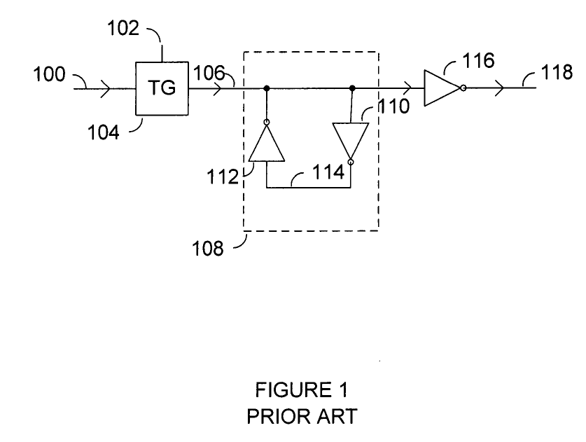

FIG. 1 is a schematic diagram of a transfer gate, a latch, and an inverter. An input, 100, is connected to the input of transfer gate, 104. The output, 106, of the transfer gate, 104, is connected to the input/output of the latch, 108. Control signal, 102, controls when the signal on the input, 100, of the transfer gate, 104, is transferred to the output, 106, of the transfer gate, 104. The signal presented at the output, 106, is stored on the latch, 108. The signal, 106, stored on the latch, 108, drives the input, 106, of the inverter, 116. In this example, the output, 118, of the inverter, 116, has the opposite sense of the signal stored on the latch, 108. In this example, a latch comprises two inverters, 110 and 112, where the output, 114, of one inverter, 110, is connected to input, 114, of another inverter, 112 and the output, 106, of one inverter, 112, is connected to the input, 106, of another inverter, 110.

After control signal, 102, is turned off, the signal, 106 on the latch, 108, is usually retained. If, however, a soft error event disturbs the charge stored on the latch, the original signal may be lost and the output, 118, of inverter, 116, may be changed from its original logical value.

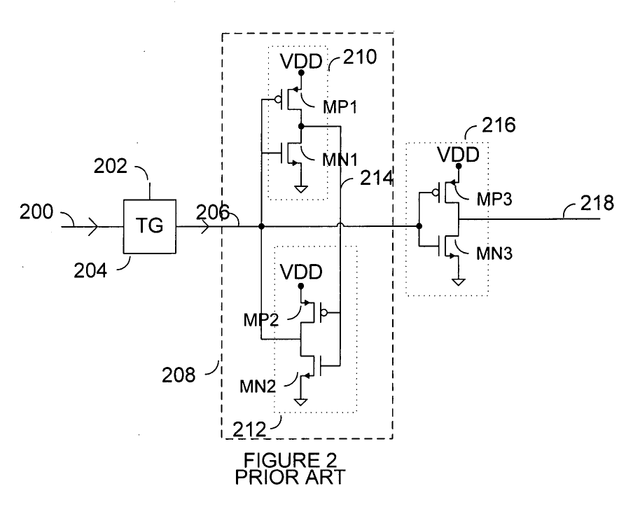

FIG. 2 is a schematic diagram of a transfer gate, a latch, and an inverter. An input, 200, is connected to the input of transfer gate, 204. The output, 206, of the transfer gate, 204, is connected to the input/output of the latch, 208. Control signal, 202, controls when the signal on the input, 200, of the transfer gate, 204, is transferred to the output, 206, of the transfer gate, 204. The signal presented at the output, 206, is stored on the latch, 208. The signal, 206, stored on the latch, 208, drives the input, 206, of the inverter, 216. In this example, the output, 218, of the inverter, 216, has the opposite sense of the signal stored on the latch, 208.

In this example, a latch, 208, comprises two inverters, 210 and 212, where the output, 214, of one inverter, 210, is connected to input, 214, of another inverter, 212 and the output, 206, of one inverter, 212, is connected to the input, 206, of another inverter, 210. In this example, inverter 210 comprises a PFET, MP1, and an NFET, MN1. The gates, 206, of PFET, MP1, and NFET, MN1, are connected. The source of PFET, MP1, is connected to VDD and the source of NFET, MN1, is connected to GND. The drains of PFET, MP1, and NFET, MN1, are connected at node 214. In this example, inverter 212 comprises a PFET, MP2, and an NFET, MN2. The gates, 214, of PFET, MP2, and NFET, MN2, are connected. The source of PFET, MP2, is connected to VDD and the source of NFET, MN2, is connected to GND. The drains of PFET, MP2, and NFET, MN2, are connected at node 206. Inverter 216 comprises a PFET, MP3, and an NFET, MN3. The gates of PFET, MP3, and NFET, MN3, are connected at node 206. The source of PFET, MP3, is connected to VDD. The source of NFET, MN3, is connected to ground. The drains of PFET, MP3, and NFET, MN3, are connected at node 218. In this example, inverters, 210, 212, and 216 were implemented using PFETs and NFETs. Other implementations of an inverter may be used.

After control signal, 202, is turned off, the signal, 206 on the latch, 208, is usually retained. If, however, a soft error event disturbs the charge stored on the latch, the original signal may be lost and the output, 218, of inverter, 216, may be changed from its original logical value.

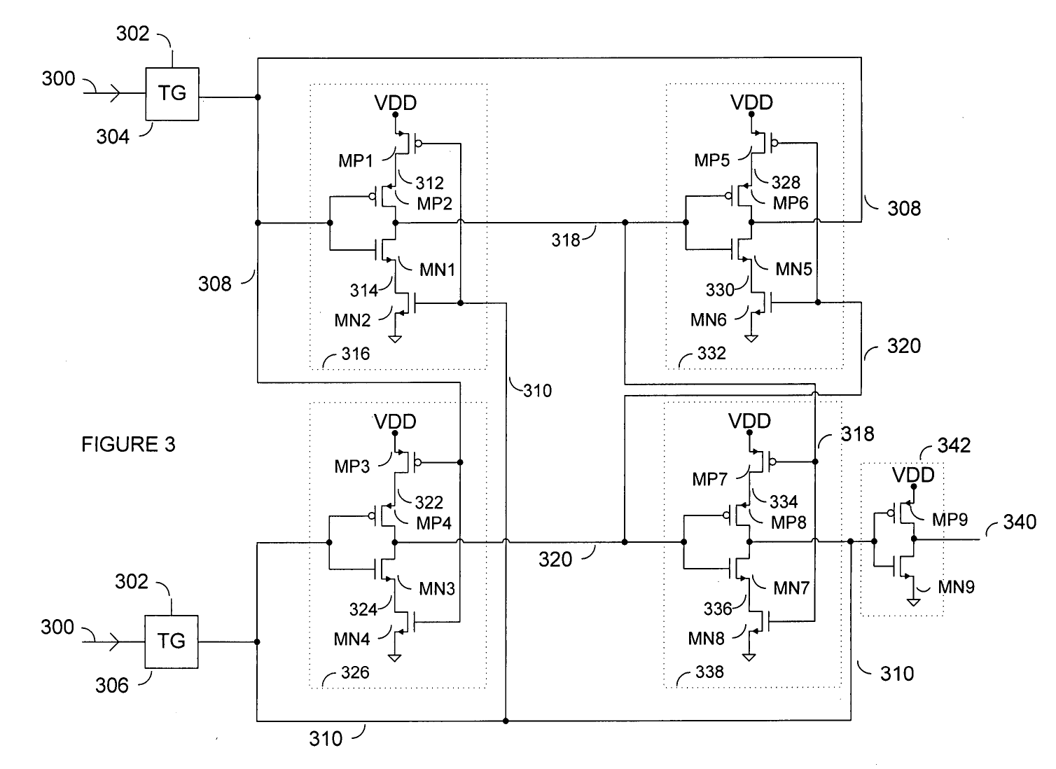

FIG. 3 is a schematic diagram of a memory element. An input, 300, is connected to the input of transfer gate, 304 and transfer gate, 306. The output, 308, of the transfer gate, 304, is connected to the first input of the tristatable inverter, 316, the second input of tristatable inverter, 326, and the output of tristatable inverter, 332. The output, 310, of the transfer gate, 306, is connected to the first input of the tristatable inverter, 326, the second input of tristatable inverter, 316, and the output of tristatable inverter, 338.

Control signal, 302, controls when the signal on the input, 300, of the transfer gate, 304, and transfer gate, 306, is transferred to the output, 308, of the transfer gate, 304, and to the output, 310, of the transfer gate, 306. The signal presented at the output, 308, of transfer gate 304 drives the first input of the tristatable inverter, 316. Since the signal presented at the output, 310, is the same signal as presented at output, 308, the second input of the tristatable inverter, 316, has the same logical value as the first input to the tristatable inverter, 316. Because the signals on the inputs of the tristatable inverter, 316, have the same logical value, the tristatable inverter, 316, acts like an inverter and outputs a signal, 318 with the opposite logical value as the input.

The signal presented at the output, 310, of transfer gate 306 drives the first input of the tristatable inverter, 326. Since the signal presented at the output, 308, is the same signal as presented at output, 310, the second input of the tristatable inverter, 326, has the same logical value as the first input to the tristatable inverter, 316. Because the signals on the inputs of the tristatable inverter, 326, have the same logical value, the tristatable inverter, 326, acts like an inverter and outputs a signal, 320 with the opposite logical value as the input.

The signal presented at the output, 318, of tristatable inverter 316 drives the first input of the tristatable inverter, 332. Since the signal presented at the output, 320, of tristatable inverter 326 is the same signal as presented at output, 318 of tristatable inverter 316, the second input of the tristatable inverter, 332, has the same logical value as the first input to the tristatable inverter, 332. Because the signals on the inputs of the tristatable inverter, 332, have the same logical value, the tristatable inverter, 332, acts like an inverter and outputs a signal, 308 with the opposite logical value as the input. The logical value on the output, 308, of tristatable inverter 332 reinforces the value, 308, on the tristatable inverter 316.

The signal presented at the output, 320, of tristatable inverter 326 drives the first input of the tristatable inverter, 338. Since the signal presented at the output, 318, of tristatable inverter 316 is the same signal as presented at output, 320 of tristatable inverter 326, the second input of the tristatable inverter, 338, has the same logical value as the first input to the tristatable inverter, 338. Because the signals on the inputs of the tristatable inverter, 338, have the same logical value, the tristatable inverter, 338, acts like an inverter and outputs a signal, 310 with the opposite logical value as the input. The logical value on the output, 310, of tristatable inverter 338 reinforces the value, 310, on the tristatable inverter 326.

After control signal, 302, is turned off, the logical values stored on nodes 308, 310, 318, and 320 are usually retained. In this embodiment, if a soft-error event disturbs node 308 and only node 308, node 308 will be recovered to its original logical value. In this embodiment, if a soft-error event disturbs node 310 and only node 310, node 310 will be recovered to its original logical value. In this embodiment, if a soft-error event disturbs node 318 and only node 318, node 318 will be recovered to its original logical value. In this embodiment, if a soft-error event disturbs node 320 and only node 320, node 320 will be recovered to its original logical value.

For example, if the memory element has a logical one stored on it and transfer gates, 304, and 306 are off, node 308 is a logical high value, node 310 is a logical high value, node 318 is a logical low value, and node 320 is a logical low value. In this example, if a soft error event disturbs node 308 from a logical high value to a logical low value, node 318 will remain a logical low value because PFET, MP1, is off and NFET, MN1 is off, tristating tristatable inverter, 316. Because tristatable inverter, 316, is tristated, node 318 retains its original low value. Since node 318 is a logical low value, tristatable inverter, 332, actively drives node 308 back to its original high logical value. Since node 308 is recovered to its original high logical value, tristatable inverter, 316, is no longer tristated. Instead tristatable inverter, 316, actively drives node 318 to a low logical value.

Another example is, if the memory element has a logical one stored on it and transfer gates, 304, and 306 are off, node 308 is a logical high value, node 310 is a logical high value, node 318 is a logical low value, and node 320 is a logical low value. In this example, if a soft error event disturbs node 310 from a logical high value to a logical low value, node 320 will remain a logical low value because PFET, MP3, is off and NFET, MN3 is off, tristating tristatable inverter, 326. Because tristatable inverter, 326, is tristated, node 320 retains its original low value. Since node 320 is a logical low value, tristatable inverter, 338, actively drives node 310 back to its original high logical value. Since node 310 is recovered to its original high logical value, tristatable inverter, 326, is no longer tristated. Instead tristatable inverter, 326, actively drives node 320 to a low logical value.

Another example is, if the memory element has a logical one stored on it and transfer gates 304 and 306 are off, node 308 is a logical high value, node 310 is a logical high value, node 318 is a logical low value, and node 320 is a logical low value. In this example, if a soft error event disturbs node 318 from a logical low value to a logical high value, node 308 will remain a logical high value because PFET, MP6, is off and NFET, MN6 is off, tristating tristatable inverter, 332. Because tristatable inverter, 332, is tristated, node 308 retains its original high value. Since node 308 is a logical high value, tristatable inverter, 316, actively drives node 318 back to its original low logical value. Since node 318 is recovered to its original low logical value, tristatable inverter, 332, is no longer tristated. Instead tristatable inverter, 332, actively drives node 308 to a high logical value.

Another example is, if the memory element has a logical one stored on it and transfer gates 304 and 306 are off, node 308 is a logical high value, node 310 is a logical high value, node 318 is a logical low value, and node 320 is a logical low value. In this example, if a soft error event disturbs node 320 from a logical low value to a logical high value, node 310 will remain a logical high value because PFET, MP8, is off and NFET, MN8 is off, tristating tristatable inverter, 338. Because tristatable inverter, 338, is tristated, node 310 retains its original high value. Since node 310 is a logical high value, tristatable inverter, 326, actively drives node 320 back to its original low logical value. Since node 320 is recovered to its original low logical value, tristatable inverter, 338, is no longer tristated. Instead tristatable inverter, 338, actively drives node 310 to a high logical value.

If a soft error event disturbs a single node and a single node only in the memory element shown in FIG. 3, the memory element will recover the single disturbed node back to its original logical value. These nodes include nodes 308, 310, 312, 314, 318, 320, 322, 324, 328, 330, 334, and 336.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A memory element with an improved soft-error rate comprising:
a) a first transfer gate, the first transfer gate having a data input, a control input and an output;
b) a second transfer gate, the second transfer gate having a data input, a control input and an output;
c) an inverter, the inverter having an input and an output;
d) a first tristatable inverter, the first tristatable inverter having a first input, a second input, and an output;
e) a second tristatable inverter, the second tristatable inverter having a first input, a second input, and an output;
f) a third tristatable inverter, the third tristatable inverter having a first input, a second input, and an output;
g) a fourth tristatable inverter, the fourth tristatable inverter having a first input, a second input, and an output;
h) wherein the input of the memory element is connected to the data input of the first and second transfer gates;
i) wherein a control signal is connected to the control input of the first and second transfer gates;
j) wherein the output of the memory element is connected to the output of the inverter;
k) wherein the output of the first transfer gate is connected to the first input of the first tristatable inverter, the second input of the second tristatable inverter, and the output of the third tristatable inverter;
l) wherein the output of the second transfer gate is connected to the first input of the second tristatable inverter, the second input of the first tristatable inverter, the output of the fourth tristatable inverter, and the input to the inverter;
m) wherein the output of the first tristatable inverter is connected to the first input of the third tristatable inverter and the second input of the fourth tristatable inverter;
n) wherein the output of the second tristatable inverter is connected to the first input of the fourth tristatable inverter and the second input of the third tristatable inverter.

2) The memory element as in claim 1 wherein the first tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the first tristatable inverter;
i) wherein the source of the first NFET is connected to the drain of the second NFET;
j) wherein the gate of the second PFET and the gate of the first NFET are connected to the first input of the first tristatable inverter;
k) wherein the gate of the first PFET and the gate of the second NFET are connected to the second input of the first tristatable inverter.

3) The memory element as in claim 1 wherein the second tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the second tristatable inverter;
i) wherein the source of the first NFET is connected to the drain of the second NFET;
j) wherein the gate of the second PFET and the gate of the first NFET are connected to the first input of the second tristatable inverter;
k) wherein the gate of the first PFET and the gate of the second NFET are connected to the second input of the second tristatable inverter.

4) The memory element as in claim 1 wherein the third tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the third tristatable inverter;
i) wherein the source of the first NFET is connected to the drain of the second NFET;
j) wherein the gate of the second PFET and the gate of the first NFET are connected to the first input of the third tristatable inverter;
k) wherein the gate of the first PFET and the gate of the second NFET are connected to the second input of the third tristatable inverter.

5) The memory element as in claim 1 wherein the fourth tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the fourth tristatable inverter;
i) wherein the source of the first NFET is connected to the drain of the second NFET;
j) wherein the gate of the second PFET and the gate of the first NFET are connected to the first input of the fourth tristatable inverter;
k) wherein the gate of the first PFET and the gate of the second NFET are connected to the second input of the fourth tristatable inverter.

6) The memory element as in claim 1 wherein the first transfer gate comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the data input of the first transfer gate is connected to the drain of the first PFET and the drain of the first NFET;
f) wherein the output of the first transfer gate is connected to the source of the first PFET and the source of the first NFET;
g) wherein the control input of the first transfer gate is connected to the gate of the first NFET, the gate of the second NFET, and the gate of the second PFET;
h) wherein the gate of the first PFET is connected to the drain of the second NFET and the drain of the second PFET;
i) wherein the source of the second PFET is connected to VDD;
j) wherein the source of the second NFET is connected to GND.

7) The memory element as in claim 1 wherein the second transfer gate comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the data input of the second transfer gate is connected to the drain of the first PFET and the drain of the first NFET;
f) wherein the output of the second transfer gate is connected to the source of the first PFET and the source of the first NFET;
g) wherein the control input of the second transfer gate is connected to the gate of the first NFET, the gate of the second NFET, and the gate of the second PFET;
h) wherein the gate of the first PFET is connected to the drain of the second NFET and the drain of the second PFET;
i) wherein the source of the second PFET is connected to VDD;
j) wherein the source of the second NFET is connected to GND.

8) A memory element with an improved soft-error rate comprising:
a) a first transfer gate, the first transfer gate having a data input, a control input and an output;
b) a second transfer gate, the second transfer gate having a data input, a control input and an output;
c) a buffer, the buffer having an input and an output;
d) a first tristatable inverter, the first tristatable inverter having a first input, a second input, and an output;
e) a second tristatable inverter, the second tristatable inverter having a first input, a second input, and an output;
f) a third tristatable inverter, the third tristatable inverter having a first input, a second input, and an output;
g) a fourth tristatable inverter, the fourth tristatable inverter having a first input, a second input, and an output;
h) wherein the input of the memory element is connected to the data input of the first and second transfer gates;
i) wherein a control signal is connected to the control input of the first and second transfer gates;
j) wherein the output of the memory element is connected to the output of the buffer;
k) wherein the output of the first transfer gate is connected to the first input of the first tristatable inverter, the second input of the second tristatable inverter, and the output of the third tristatable inverter;
l) wherein the output of the second transfer gate is connected to the first input of the second tristatable inverter, the second input of the first tristatable inverter, the output of the fourth tristatable inverter, and the input to the buffer;
m) wherein the output of the first tristatable inverter is connected to the first input of the third tristatable inverter and the second input of the fourth tristatable inverter;
n) wherein the output of the second tristatable inverter is connected to the first input of the fourth tristatable inverter and the second input of the third tristatable inverter.

9) The memory element as in claim 8 wherein the first tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the first tristatable inverter;
i) wherein the source of the first NFET is connected to the drain of the second NFET;
j) wherein the gate of the second PFET and the gate of the first NFET are connected to the first input of the first tristatable inverter;
k) wherein the gate of the first PFET and the gate of the second NFET are connected to the second input of the first tristatable inverter.

10) The memory element as in claim 8 wherein the second tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the second tristatable inverter;
i) wherein the source of the first NFET is connected to the drain of the second NFET;
j) wherein the gate of the second PFET and the gate of the first NFET are connected to the first input of the second tristatable inverter;
k) wherein the gate of the first PFET and the gate of the second NFET are connected to the second input of the second tristatable inverter.

11) The memory element as in claim 8 wherein the third tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the third tristatable inverter;
i) wherein the source of the first NFET is connected to the drain of the second NFET;
j) wherein the gate of the second PFET and the gate of the first NFET are connected to the first input of the third tristatable inverter;
k) wherein the gate of the first PFET and the gate of the second NFET are connected to the second input of the third tristatable inverter.

12) The memory element as in claim 8 wherein the fourth tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the fourth tristatable inverter;
i) wherein the source of the first NFET is connected to the drain of the second NFET;
j) wherein the gate of the second PFET and the gate of the first NFET are connected to the first input of the fourth tristatable inverter;
k) wherein the gate of the first PFET and the gate of the second NFET are connected to the second input of the fourth tristatable inverter.

13) The memory element as in claim 8 wherein the first transfer gate comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the data input of the first transfer gate is connected to the drain of the first PFET and the drain of the first NFET;
f) wherein the output of the first transfer gate is connected to the source of the first PFET and the source of the first NFET;
g) wherein the control input of the first transfer gate is connected to the gate of the first NFET, the gate of the second NFET, and the gate of the second PFET;
h) wherein the gate of the first PFET is connected to the drain of the second NFET and the drain of the second PFET;
i) wherein the source of the second PFET is connected to VDD;
j) wherein the source of the second NFET is connected to GND.

14) The memory element as in claim 8 wherein the second transfer gate comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the data input of the second transfer gate is connected to the drain of the first PFET and the drain of the first NFET;
f) wherein the output of the second transfer gate is connected to the source of the first PFET and the source of the first NFET;
g) wherein the control input of the second transfer gate is connected to the gate of the first NFET, the gate of the second NFET, and the gate of the second PFET;
h) wherein the gate of the first PFET is connected to the drain of the second NFET and the drain of the second PFET;
i) wherein the source of the second PFET is connected to VDD;
j) wherein the source of the second NFET is connected to GND.

15) The memory element as in claim 8 wherein the buffer comprises:
a) a first inverter, the first inverter having an input and an output;
b) a second inverter, the second inverter having an input and an output;
c) wherein the input of the buffer is connected to the input of the first inverter;
d) wherein the output of the buffer is connected to the output of the second inverter;
e) wherein the output of the first inverter is connected to the input of the second inverter.

16) A method for manufacturing a memory element with an improved soft-error rate comprising:
a) fabricating a first transfer gate, the first transfer gate having a data input, a control input and an output;
b) fabricating a second transfer gate, the second transfer gate having a data input, a control input and an output;
c) fabricating an inverter, the inverter having an input and an output;
d) fabricating a first tristatable inverter, the first tristatable inverter having a first input, a second input, and an output;
e) fabricating a second tristatable inverter, the second tristatable inverter having a first input, a second input, and an output;
f) fabricating a third tristatable inverter, the third tristatable inverter having a first input, a second input, and an output;
g) fabricating a fourth tristatable inverter, the fourth tristatable inverter having a first input, a second input, and an output;
h) wherein the input of the memory element is connected to the data input of the first and second transfer gates;
i) wherein a control signal is connected to the control input of the first and second transfer gates;
j) wherein the output of the memory element is connected to the output of the inverter;
k) wherein the output of the first transfer gate is connected to the first input of the first tristatable inverter, the second input of the second tristatable inverter, and the output of the third tristatable inverter;
l) wherein the output of the second transfer gate is connected to the first input of the second tristatable inverter, the second input of the first tristatable inverter, the output of the fourth tristatable inverter, and the input to the inverter;
m) wherein the output of the first tristatable inverter is connected to the first input of the third tristatable inverter and the second input of the fourth tristatable inverter;
n) wherein the output of the second tristatable inverter is connected to the first input of the fourth tristatable inverter and the second input of the third tristatable inverter.

17) The method as in claim 16 wherein the first tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the first tristatable inverter;
i) wherein the source of the first NFET is connected to the drain of the second NFET;
j) wherein the gate of the second PFET and the gate of the first NFET are connected to the first input of the first tristatable inverter;
k) wherein the gate of the first PFET and the gate of the second NFET are connected to the second input of the first tristatable inverter.

18) The method as in claim 16 wherein the second tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the second tristatable inverter;
i) wherein the source of the first NFET is connected to the drain of the second NFET;
j) wherein the gate of the second PFET and the gate of the first NFET are connected to the first input of the second tristatable inverter;
k) wherein the gate of the first PFET and the gate of the second NFET are connected to the second input of the second tristatable inverter.

19) The method as in claim 16 wherein the third tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the third tristatable inverter;
i) wherein the source of the first NFET is connected to the drain of the second NFET;
j) wherein the gate of the second PFET and the gate of the first NFET are connected to the first input of the third tristatable inverter;
k) wherein the gate of the first PFET and the gate of the second NFET are connected to the second input of the third tristatable inverter.

20) The method as in claim 16 wherein the fourth tristatable inverter comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the source of the first PFET is connected to VDD;
f) wherein the source of the second NFET is connected to GND;
g) wherein the drain of the first PFET is connected to the source of the second PFET;
h) wherein the drain of the second PFET and the drain of the first NFET are connected to the output of the fourth tristatable inverter;
i) wherein the source of the first NFET is connected to the drain of the second NFET;
j) wherein the gate of the second PFET and the gate of the first NFET are connected to the first input of the fourth tristatable inverter;
k) wherein the gate of the first PFET and the gate of the second NFET are connected to the second input of the fourth tristatable inverter.

21) The method as in claim 16 wherein the first transfer gate comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the data input of the first transfer gate is connected to the drain of the first PFET and the drain of the first NFET;
f) wherein the output of the first transfer gate is connected to the source of the first PFET and the source of the first NFET;
g) wherein the control input of the first transfer gate is connected to the gate of the first NFET, the gate of the second NFET, and the gate of the second PFET;
h) wherein the gate of the first PFET is connected to the drain of the second NFET and the drain of the second PFET;
i) wherein the source of the second PFET is connected to VDD;
j) wherein the source of the second NFET is connected to GND.

22) The method as in claim 16 wherein the second transfer gate comprises:
a) a first PFET, the first PFET having a gate, drain and source;
b) a second PFET, the second PFET having a gate, drain and source;
c) a first NFET, the first NFET having a gate, drain and source;
d) a second NFET, the second NFET having a gate, drain and source;
e) wherein the data input of the second transfer gate is connected to the drain of the first PFET and the drain of the first NFET;
f) wherein the output of the second transfer gate is connected to the source of the first PFET and the source of the first NFET;
g) wherein the control input of the second transfer gate is connected to the gate of the first NFET, the gate of the second NFET, and the gate of the second PFET;
h) wherein the gate of the first PFET is connected to the drain of the second NFET and the drain of the second PFET;
i) wherein the source of the second PFET is connected to VDD;
j) wherein the source of the second NFET is connected to GND.
